(19) United States
(12) Patent Application Publication
(10) Pub. No.: US 2025/0158603 A1
(43) Pub. Date: May 15, 2025

(54) INTEGRATOR SYSTEM RESPONSE STABILIZATION

(71) Applicant: TEXAS INSTRUMENTS INCORPORATED, Dallas, TX (US)

(72) Inventors: Anmol Sharma, Santa Clara, CA (US); Orlando Lazaro, Dallas, CA (US)

(21) Appl. No.: 18/508,565

(22) Filed: Nov. 14, 2023

(51) Int. Cl. H03K 5/01; H03K 3/01; H03K 5/24; H03K 17/56

(52) U.S. Cl. CPC H03K 5/01; H03K 3/01; H03K 5/24; H03K 17/56

(57) ABSTRACT

The techniques and circuits, described herein, include solutions for compensating for integrator drift. A drift compensation circuit has a first terminal coupled to an output of an integrator, and a second terminal coupled to an input of the integrator. The drift compensation circuit is configured to sense integrator drift at the output of the integrator, and provide a compensation signal to the input of the integrator based on the sensed drift. The input of the integrator may be coupled to an output of an additional integrator. By sensing the integrator drift at the end of the signal chain, and providing the compensation signal earlier in the signal chain, the compensation signal can compensate for integrator drift from multiple integrators in the system.

### BACKGROUND

An integrator is an electronic device that outputs a mathematical integration of an input signal. Integrators can be used in a wide variety of applications, such as control circuitry, analog circuitry, etc.

### SUMMARY

A circuit includes a first integrator, a second integrator, a pulse generator, and a drift compensation circuit. The first integrator has a first input, a second input, and an output. The second integrator has a first input, a second input coupled to the output of the first integrator, and an output. The pulse generator has a control input coupled to the output of the second integrator, and an output. The drift compensation circuit has a first terminal coupled to the output of the second integrator, and a second terminal coupled to the output of the first integrator.

A circuit includes a first integrator and a drift compensation circuit. The first integrator has a first input, a second input, and an output. The first integrator includes a first amplifier, a first resistor, a second resistor, and a first capacitor. The first amplifier has a first input coupled to the first input of the first integrator, a second input, and an output coupled to the output of the first integrator. The first resistor has a first terminal coupled to the second input of the first integrator, and a second terminal coupled to the second input of the first amplifier. The second resistor has a first terminal coupled to the second input of the first integrator, and a second terminal. The first capacitor has a first terminal coupled to the second terminal of the second resistor, and a second terminal coupled to the output of the first amplifier. The drift compensation circuit has a first terminal coupled to the output of the first integrator, a second terminal coupled to the first terminal of the first capacitor, and a third terminal.

A circuit includes a first integrator, a second integrator, and a drift compensation circuit. The first integrator includes a first amplifier, and a first capacitor. The first amplifier has a first input, a second input, and an output. The first capacitor is coupled to the output of the first amplifier. The second integrator includes a second amplifier, and a second capacitor. The second amplifier has a first input, a second input coupled to the output of the first amplifier, and an output. The second capacitor is coupled to the output of the second amplifier. The drift compensation circuit has a sensing terminal coupled to the output of the second amplifier, and an output terminal coupled to the first capacitor. The drift compensation circuit is configured to provide a current to the first capacitor based on a current or voltage sensed at the output of the second amplifier.

### BRIEF DESCRIPTION OF THE DRAWINGS

FIG. 1 is a circuit schematic illustrating a drift compensation circuit coupled to first and second integrators, in an example.

FIGS. 2-3 are circuit schematics illustrating examples of the drift compensation circuit and first and second integrators of FIG. 1.

FIG. 4 is a circuit schematic illustrating an example of a drift compensation circuit coupled to a first plurality of integrators.

FIGS. 5A-5B are waveform diagrams illustrating examples of light load operation.

FIG. 6 is a circuit schematic illustrating an example of further details of FIG. 2.

FIG. 7 is a circuit schematic illustrating an example of further details of FIG. 3 or 4.

### DETAILED DESCRIPTION

The drawings are not drawn to scale.

An integrator is an electronic device that outputs a signal that reflects a mathematical integration of an input signal. For example, an integrator may output a voltage signal that is the integration of a differential voltage signal received on its inputs.

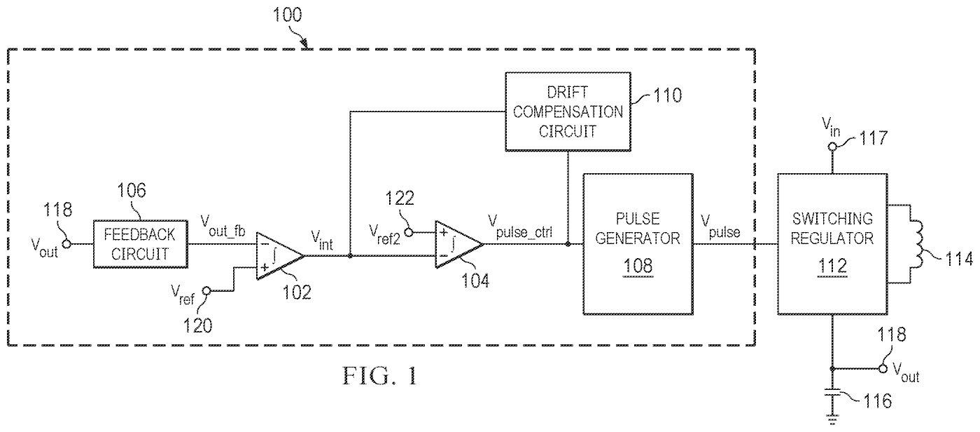

FIG. 1 illustrates an example of a control circuit 100 including a first integrator 102 and a second integrator 104. The control circuit 100 also includes a feedback circuit 106, a pulse generator 108, and a drift compensation circuit 110. Further illustrated is a switching regulator 112, an inductor 114, and a capacitor 116. In some examples, the first integrator 102, second integrator 104, feedback circuit 106, pulse generator 108, and drift compensation circuit 110 are part of a same semiconductor substrate or chip, while the switching regulator 112, inductor 114, and/or capacitor 116 are external to the chip.

In the example of FIG. 1, the drift compensation circuit 110 may be used to compensate for integrator drift at the outputs of the first and second integrators 102, 104 to improve performance by improving transient response, output voltage ripple, etc. Further details of integrator drift and the drift compensation circuit 110 are described below.

The switching regulator 112 has a control input upon which a signal Vₚᵤₗₛₑ is received, an input terminal 117 upon which a signal Vᵢₙ is received, and an output terminal 118 upon which a signal Vₒᵤₜ is provided. The switching regulator also has first and second terminals coupled to first and second terminals of the inductor 114 respectively. The capacitor 116 has a first terminal coupled to the output terminal 118, and a second terminal coupled to ground.

The first integrator 102 has a first input, a second input, and an output. The first input is coupled to a first reference voltage terminal 120, upon which a signal V_{ref} is received. A signal V_{out_fb} is received upon the second input, which is coupled to the output terminal 118 via the feedback circuit 106. Accordingly, the feedback circuit 106 has a first terminal coupled to the output terminal 118, and a second terminal coupled to the second input of the first integrator 102. The first integrator 102 provides a signal Vᵢₙₜ at its output based on (e.g., based on an integration of) the signals V_{ref} and V_{out_fb}.

The second integrator 104 has a first input, a second input, and an output. The first input is coupled to a second reference voltage terminal 122, upon which a signal V_{ref2} is received. The signal Vᵢₙₜ is received on the second input, which is coupled to the output of the first integrator 102. The second integrator 104 provides a signal V_{pulse_ctrl} at its output based on (e.g., based on an integration of) the signals V_{ref2} and Vᵢₙₜ.

The pulse generator 108 has a control input coupled to the output of the second integrator 104, and an output coupled to the control input of the switching regulator 112. The pulse generator 108 provides a signal Vₚᵤₗₛₑ at its output based on the signal V_{pulse_ctrl} received on its control input.

The drift compensation circuit 110 has a first terminal coupled to the output of the second integrator 104, and a second terminal of the second integrator 104.

The switching regulator 112 may be a direct current (DC) to DC converter that is controlled by switching operation, such as a buck converter, a boost converter, a buck-boost converter, etc. In the illustrated example, the switching regulator 112 provides a regulated voltage Vₒᵤₜ at the output terminal 118 based on a voltage Vᵢₙ at the input terminal 117 and a control signal Vₚᵤₗₛₑ. The control signal Vₚᵤₗₛₑ may be a pulse signal (e.g., one or more pulses of voltage with respect to time), such as a pulse width modulation (PWM) signal or a pulse frequency modulation (PFM) signal. Based on the control signal Vₚᵤₗₛₑ, the switching regulator 112 opens/closes one or more switches within the switching regulator to alternate between storing energy in the inductor 114 (e.g., in the form of a magnetic field) and releasing energy from the inductor 114. The inductor 114 may be coupled to the capacitor 116, and the energy stored in the inductor 114 may be used to charge the capacitor 116 during switching operation. The capacitor 116 may be discharged by a load at the output terminal 118. Similar to the inductor 114, the capacitor 116 may alternate between being charged/discharged by opening/closing the one or more switches, causing the voltage Vₒᵤₜ to oscillate around a particular voltage. The switching operation may occur at a high frequency, such that the voltage oscillation has a small magnitude and the voltage Vₒᵤₜ can be considered regulated to the particular voltage.

In some examples, the control circuit 100 is used to control the switching operation of the switching regulator 112. The signals V_{out_fb}, V_{ref}, V_{ref2}, Vᵢₙₜ, V_{pulse_ctrl} may be voltage signals used at various points within the control circuit 100 to generate the signal Vₚᵤₗₛₑ used to control the switching regulator 112. Accordingly, the signals V_{out_fb}, V_{ref}, V_{ref2}, Vᵢₙₜ, V_{pulse_ctrl} may also be referred to herein as voltages.

Based on feedback from Vₒᵤₜ, the feedback circuit 106 provides V_{out_fb} to the second input of the first integrator 102. For example, the signal Vₒᵤₜ may be scaled down by the feedback circuit 106 to produce V_{out_fb}. The signal V_{out_fb} may be passed through a signal chain including the first integrator 102 and the second integrator 104 to produce the signal V_{pulse_ctrl}, which is provided to the pulse generator 108.

The first integrator 102 provides the signal Vᵢₙₜ based on an integration of a differential voltage between the V_{ref} and V_{out_fb}. The voltage V_{ref} may be used to set a voltage regulation target for the voltage Vₒᵤₜ. Accordingly, when Vₒᵤₜ is at the voltage regulation target, V_{out_fb} is equal to V_{ref}, and the voltage Vᵢₙₜ remains constant. When the Vₒᵤₜ is below the voltage regulation target, V_{out_fb} is less than V_{ref}, and the voltage Vᵢₙₜ increases. Similarly, when Vₒᵤₜ is above the voltage regulation target, V_{out_fb} is greater than V_{ref}, and the voltage Vᵢₙₜ decreases.

The second integrator 104 provides the signal V_{pulse_ctrl} based on an integration of a differential voltage between V_{ref2} and Vᵢₙₜ. Depending on whether Vᵢₙₜ is greater than, less than, or equal to V_{ref2}, the voltage V_{pulse_ctrl} will decrease, increase, or remain constant respectively. The voltage V_{ref2} may be, for example, 1 Volt (V).

In some examples, the pulse generator 108 generates the signal Vₚᵤₗₛₑ as a PWM signal based on the signal V_{pulse_ctrl}. For example, the pulse generator 108 compares the voltage V_{pulse_ctrl} to a reference waveform (e.g., a triangle or sawtooth waveform), outputting “high” when the voltage V_{pulse_ctrl} exceeds a voltage of the reference waveform, and outputting “low” when the voltage V_{pulse_ctrl} is less than the voltage of the reference waveform, resulting in a PWM signal. A frequency of the PWM signal is determined by a frequency of the reference waveform, and a duty cycle (e.g., pulse width) of the PWM signal is determined by a magnitude of the voltage V_{pulse_ctrl} relative to a magnitude of the reference waveform. The PWM signal is used to control the output voltage Vₒᵤₜ by controlling the switching operation of the switching regulator 112. Depending on whether the PWM signal is “high” or “low”, the switching regulator 112 may operate in different states. In a first state (e.g., during PWM “high”), the switching regulator 112 charges the inductor 114. In a second state (e.g., during PWM “low”), the switching regulator 112 discharges the inductor 114, for example, by providing the stored inductor energy to a load coupled to the output terminal 118. The switching regulator 112 may change between the first and second states by opening/closing appropriate switches within the switching regulator. The switches may be transistors, such as field-effect transistors (FETs), bipolar junction transistors (BJTs), or the like. In some examples, one or more diodes may be used in place of one or more of the switches.

In certain scenarios, the load at the output terminal 118 draws little to no current, referred to as a “light load” or “ultra-light load” operation. In such scenarios, the high frequency of the PWM signal may cause excess energy to be delivered the load, causing the voltage Vₒᵤₜ to rise above the voltage regulation target. In such scenarios, an alternative type of pulse signal, PFM, may be used during light load operation to precisely deliver a minimal amount of energy to the load. The pulse generator 108 may send each pulse of the PFM signal with a fixed minimum amount of energy (e.g., using a fixed amplitude and duration), and modulate a frequency at which the pulses are sent. By using PFM, the pulse frequency can be reduced sufficiently to allow the light load to drain the energy delivered by the previous pulse before sending another pulse.

During light load operation, the output voltage Vₒᵤₜ may remain above the voltage regulation target for an extended period of time between PFM pulses. As a result, V_{out_fb} also remains above V_{ref} between the PFM pulses. For example, V_{out_fb} is greater than V_{ref} between PFM pulses, and V_{out_fb} decreases as the load dissipates the energy stored in the capacitor 116. After V_{out_fb} reaches V_{ref}, the pulse generator 108 sends another PFM pulse and the process is repeated. While V_{out_fb} remains above V_{ref} in between pulses, the difference between V_{ref} and V_{out_fb} is integrated by the first integrator 102. The output of the first integrator 102 moves in a single direction (e.g., decreases) for an extended period of time, referred to as “integrator drift”. This effect propagates throughout the signal chain, affecting the second integrator 104 in a similar manner. Integrator drift can have several undesirable effects, such as poor transient response and increased output voltage ripple. The voltage at the output of the integrator takes time to swing in the opposite direction of the drift, resulting in poor transient response. Furthermore, transmission of PFM pulses may be delayed due to the integrator drift, resulting in PFM “bursting”, where multiple PFM pulses are sent in a single “burst”. PFM bursting increases the amount of energy delivered to the load in a short period of time, causing a larger rise in output voltage and increasing output voltage ripple.

Accordingly, in order to compensate for integrator drift during light load operation, the control circuit 100 includes the drift compensation circuit 110. The drift compensation circuit 110 is configured to sense integrator drift at the output of the second integrator 104 using its first terminal, which may also be referred to as a sensing terminal. Upon sensing the integrator drift, the drift compensation circuit 110 provides a compensation signal to the output of the first integrator 102 via its second terminal, which may also be referred to as an output terminal. The drift compensation circuit 110 may provide the compensation signal based on the sensed integrator drift. For example, a magnitude of the compensation signal may vary depending on a magnitude of the sensed drift. The compensation signal compensates for integrator drift at the output of the first integrator 102, before the integrator drift propagates throughout the signal chain (e.g., the second integrator 104), resulting in improved transient response and output voltage ripple. Although the drift compensation circuit 110 will generally be described in the context of a multi integrator system (e.g., including integrators 102, 104), the drift compensation circuit 110 may also be applied to a single integrator system (e.g., integrator 102 or integrator 104 only). For example, the output terminal of the drift compensation circuit 110 is coupled to an output of the single integrator (e.g., to an output capacitor of the single integrator) or to an input of the single integrator to provide the drift compensation signal to the output or the input of the single integrator. Further details of the drift compensation circuit 110 will now be described with reference to the following figures.

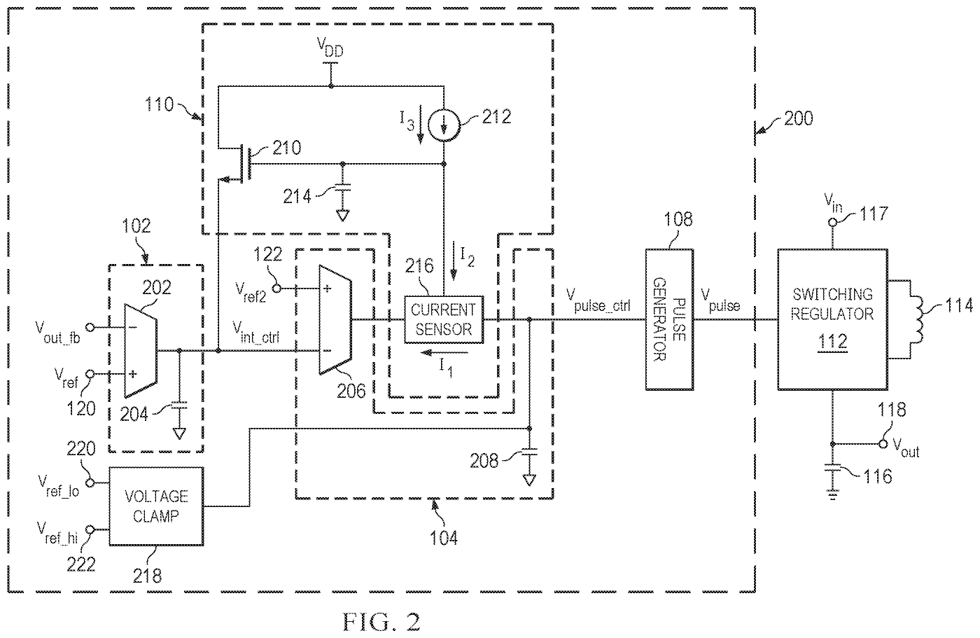

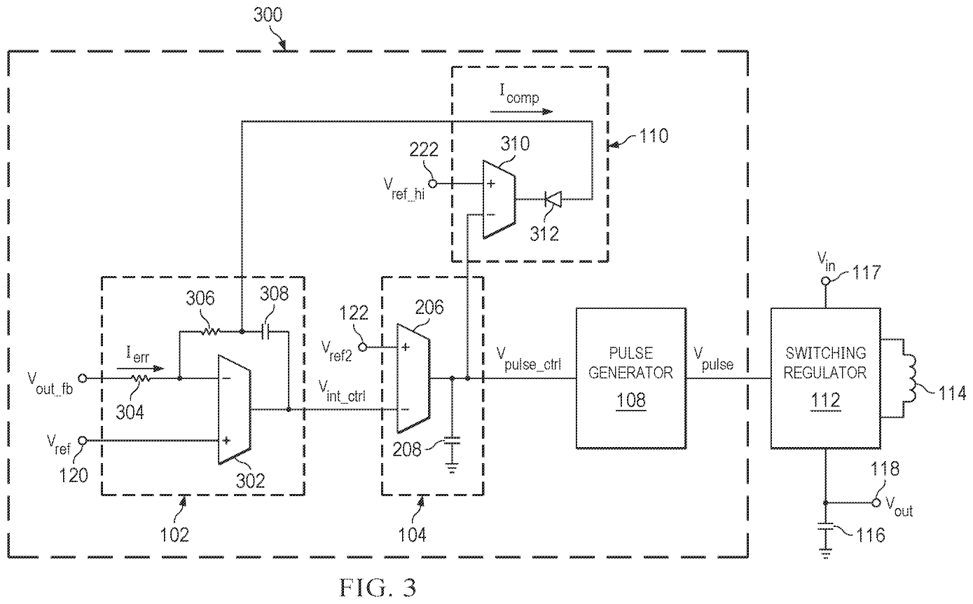

FIGS. 2-3 illustrate examples of control circuits 200, 300 including the first integrator 102, the second integrator 104, the pulse generator 108, and the drift compensation circuit 110 of FIG. 1. Further illustrated is the switching regulator 112, inductor 114, capacitor 116, input terminal 117, output terminal 118, first reference voltage terminal 120, and second reference voltage terminal 122, which may be consistent with similarly numbered elements described with reference to FIG. 1.

With reference to FIG. 2, the control circuit 200 further includes a voltage clamp 218. As shown, the first integrator 102 includes a first amplifier 202 and a first capacitor 204, and the second integrator 104 includes a second amplifier 206 and a second capacitor 208. The drift compensation circuit 110 includes a first transistor 210, a current source 212, a third capacitor 214, and a current sensor 216. In some examples, the first transistor 210 is an N-channel metal-oxide-semiconductor (NMOS) transistor.

The first amplifier 202 has a first input, a second input, and an output, which are coupled to the first input, second input, and output of the first integrator 102 respectively. The first capacitor 204 has a first terminal coupled to the output of the first amplifier 202, and a second terminal coupled to ground. The second amplifier 206 has a first input, a second input, and an output, which are coupled to the first input, second input, and output of the second integrator 104 respectively. The second capacitor 206 has a first terminal coupled to the output of the second amplifier 206, and a second terminal coupled to ground.

The first transistor 210 has a first terminal, a second terminal coupled to the second terminal of the drift compensation circuit 110, and a control terminal. The current source 212 has a first terminal coupled to the first terminal of the first transistor 210, and a second terminal coupled to the control terminal of the first transistor 210. The third capacitor 214 has a first terminal coupled to the control terminal of the first transistor 210, and a second terminal coupled to ground. As shown, the first terminal of the first transistor 210 and the first terminal of the current source 212 may be coupled to a supply voltage V_{DD}. The current sensor 216 has first and second terminals (also referred to as first and second sensing terminals) coupled in series with the output of the second amplifier 206. Accordingly, the first terminal is coupled to the output of the second amplifier 206, and the second terminal is coupled to the first terminal of the second capacitor 208. The current sensor 216 further has an output coupled to the first terminal of the third capacitor 214.

The voltage clamp has a first input upon which a signal V_{ref_lo} is received, a second input upon which a signal V_{ref_hi} is received, and an output.

In some examples, the first and second amplifiers 202, 206 are transconductance amplifiers. For example, the first amplifier 202 provides a current at its output equal to a difference between the voltages V_{ref} and V_{out_fb} multiplied by a transconductance gain of the first amplifier 202. The current charges the first capacitor 204, and the voltage V_{int_ctrl} reflects the integration of the difference between the voltages V_{ref} and V_{out_fb}. The second amplifier 206 functions in a similar manner, charging the second capacitor 208 to provide the integration of the difference between V_{ref2} and V_{int_ctrl} as V_{pulse_ctrl}.

The drift compensation circuit 110 is configured to provide a compensation signal to the output of the first integrator 102 based on a drift sensed at the output of the second integrator 104, as previously described. In some examples, sensing the drift at the output of the second integrator 104 includes sensing a current I₁. The voltage V_{ref2} may be less than V_{int_ctrl}, such that the current I₁ flows from the second capacitor 208 to the output of the second amplifier 206, as shown. The current source 212 produces (e.g., sinks) a current I₂ flowing into the current sensor 216. The third capacitor 214 is charged by a current determined by a difference between a current I₃ provided by the current source 212 and the current I₂.

During light load operation, V_{out_fb} is greater than V_{ref}, causing the voltage V_{int_ctrl} at the output of the first integrator 102 to drift. Accordingly, the first amplifier 202 sinks current and the voltage on the first capacitor 204 decreases. In turn, the current I₁ decreases, causing the current I₂ to decrease. The excess current from the current source 212 (e.g., difference between I₃ and I₂) charges the third capacitor 214, increasing a voltage on the control terminal of the first transistor 210, causing the first transistor 210 to turn on. The first transistor 210 provides the compensation signal by sourcing current to the first capacitor 204 based on the voltage on its control terminal. The current sourced by the first transistor 210 counteracts the current sunk by the first amplifier 202, preventing voltage drift at the output of the first integrator 102. By applying integrator drift compensation at the beginning of the signal chain, integrator drift for further integrator(s) in the signal chain (e.g., the second integrator 104) is also compensated.

The voltage clamp 218 is configured to clamp the voltage on the second capacitor 208 to prevent the voltage on the second capacitor 208 from falling below a minimum voltage or exceeding a maximum voltage. In some examples, the minimum voltage and the maximum voltage are set using the signals V_{ref_lo} and V_{ref_hi} received on input terminals 220 and 222 respectively. In the example of light load operation, the current I₁ may discharge the second capacitor 208, until the voltage clamp 218 clamps the capacitor voltage at V_{ref_lo}. The voltage V_{ref_lo} may be less than the voltage V_{ref_hi}. In some examples, V_{ref_lo} is a 0 volt potential (e.g., ground), and V_{ref_hi} is defined relative to Vᵢₙ (e.g., Vᵢₙ/10). Further, although the voltage clamp 218 is illustrated in the example of FIG. 2, the voltage clamp 218 may also be removed in the context of FIG. 2 while maintaining similar circuit functionality.

With reference to FIG. 3, the first integrator 102 includes a first amplifier 302, a first resistor 304, a second resistor 306, and a first capacitor 308. The second integrator 104 includes the second amplifier 206, and the second capacitor 208, which may be consistent with similarly numbered elements described with reference to FIG. 2. The drift compensation circuit 110 includes a third amplifier 310, and a diode 312.

The first amplifier 302 has a first input coupled to the first input of the first integrator 102, a second input, and an output coupled to the output of the first integrator 102. The first resistor 304 has a first terminal that is coupled to the second input of the first integrator 102 and receives the signal V_{out_fb}, and a second terminal coupled to the second input of the first amplifier 302. The second resistor 306 has a first terminal coupled to the second input of the first amplifier 302, and a second terminal. The first capacitor 308 has a first terminal coupled to the second terminal of the second resistor 306, and a second terminal coupled to the output of the first amplifier 302. The first amplifier 302 may be, for example, a voltage amplifier.

The third amplifier 310 has a first input coupled to the first terminal of the drift compensation circuit 110, a second terminal coupled to a third terminal of the drift compensation circuit 110, and an output. The third terminal of the drift compensation circuit 110 is coupled to the input terminal 222 upon which the signal V_{ref_hi} is received. The diode 312 has a first terminal coupled to the second terminal of the drift compensation circuit 110, and a second terminal coupled to the output of the third amplifier 310.

The drift compensation circuit 110 is configured to provide a compensation signal based on a drift sensed at the output of the second integrator 104. In some examples, sensing the drift at the output of the second integrator 104 includes sensing the voltage V_{pulse_ctrl} and comparing the sensed voltage to a reference voltage (e.g., V_{ref_hi}). Based on the sensed voltage and the reference voltage, the third amplifier 310 provides the compensation signal by sinking current from the first terminal of the first capacitor 308. For example, the third amplifier 310 is a transconductance amplifier.

In the example of light load operation, V_{out_fb} is greater than V_{ref}, causing a current Iₑᵣᵣ to flow through the first resistor 304 and the voltage V_{int_ctrl} at the output of the first integrator 102 to decrease (e.g., drift). In turn, the voltage V_{pulse_ctrl} on the second capacitor 208 increases until the reference voltage V_{ref_hi} is reached. After V_{pulse_ctrl} exceeds V_{ref_hi}, the third amplifier 310 provides the compensation signal by sinking a current I_{comp} from the first terminal of the first capacitor 308 through the diode 312. The current I_{comp} may be equal to the current Iₑᵣᵣ, counteracting the integrator drift and causing the voltage V_{int_ctrl} to remain constant. Similar to FIG. 2, since the drift compensation is applied at the beginning of the signal chain, integrator drift for further integrator(s) in the signal chain (e.g., the second integrator 104) is also compensated.

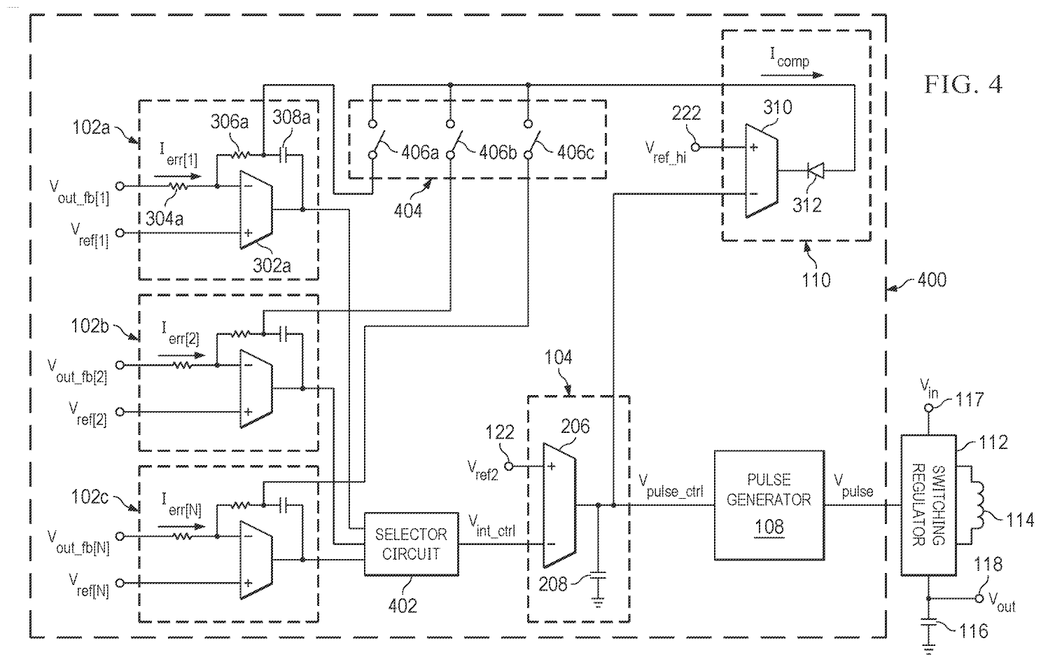

FIG. 4 illustrates an example of a control circuit 400 including a first plurality of integrators 102a, 102b, 102c, a selector circuit 402, and a switching network 404. The control circuit 400 also includes the second integrator 104, the pulse generator 108, and the drift compensation circuit 110, which may be consistent with similarly numbered elements described with reference to FIG. 3. Further illustrated is the switching regulator 112, inductor 114, capacitor 116, input terminal 117, output terminal 118, first reference voltage terminal 120, and second reference voltage terminal 122, which may be consistent with similarly numbered elements described with reference to FIGS. 1 and/or 3.

In the example of FIG. 4, each of the integrators 102a, 102b, 102c contains the same elements arranged in a similar manner as the first integrator 102 of FIG. 3. For example, the integrator 102a includes a first amplifier 302a, a first resistor 304a, a second resistor 306a, and a first capacitor 308a, which are operably coupled as shown. Each of the integrators 102a, 102b, 102c may receive respective feedback signals from the output (illustrated as V_{out_fb[1]}, V_{out_fb[2]}, V_{out_fb[N]}) and respective reference voltages (illustrated as V_{ref[1]}, V_{ref[2]}, V_{ref[N]}) on their inputs. Although the first plurality of integrators are illustrated as including three integrators 102a, 102b, 102c, in alternative examples, a different number of integrators may be used.

FIG. 4 differs from FIG. 3 in that FIG. 4 further includes the selector circuit 402, which may be used to select an integrator to be used from the first plurality of integrators 102a, 102b, 102c. The selector circuit 402 has a plurality of inputs coupled to respective outputs of the first plurality of integrators 102a, 102b, 102c, and an output coupled to the second input of the second integrator 104. The selector circuit may select an integrator from the first plurality of integrators 102a, 102b, 102c based on one or more operating conditions. For example, the selector circuit 402 is configured to select the integrator with the smallest or largest voltage at its output. The integrators 102a, 102b, 102c may be the same or different from one another depending on the design of the control circuit 400. For example, the resistance and/or capacitance of values of the integrators 102a, 102b, 102c may be the same or different.

The switching network 404 includes a plurality of switches coupled to the plurality of integrators 102a, 102b, 102c respectively. As shown, the switching network 404 includes a first switch 406a having a first terminal coupled to the second terminal of the drift compensation circuit 110, and a second terminal coupled to the first terminal of the first capacitor 308a. Similar to FIG. 3, the second terminal of the first capacitor 308a is coupled to the output of the first amplifier 302a. The switching network 404 further includes a second switch 406b and a third switch 406c, which are coupled to the integrators 102b, 102c in a similar manner.

The switching network 404 may be configured to couple the selected integrator to the drift compensation circuit 110, and decouple the unselected integrators. For example, if the selector circuit 402 selects the integrator 102a, the switching network 404 closes the switch 406a, and opens the switches 406b, 406c. Accordingly, the current I_{comp} reflects the error current of the selected integrator. In the example where the integrator 102a is selected, I_{comp} is approximately equal to L_{err[1]}. By including the switching network 404, a single drift compensation circuit (e.g., 110) can be used to compensate for integrator drift for each integrator in a multi-select integrator system, resulting in an area efficient chip design.

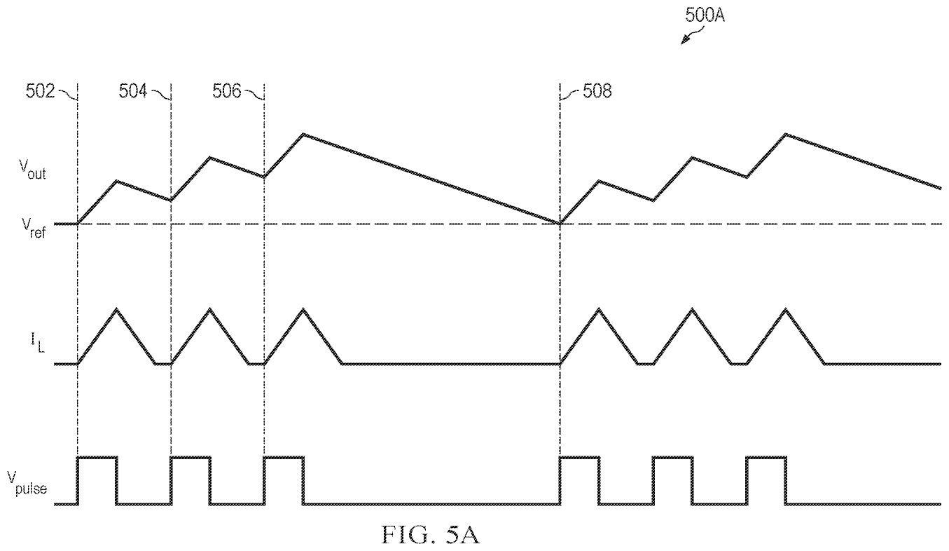

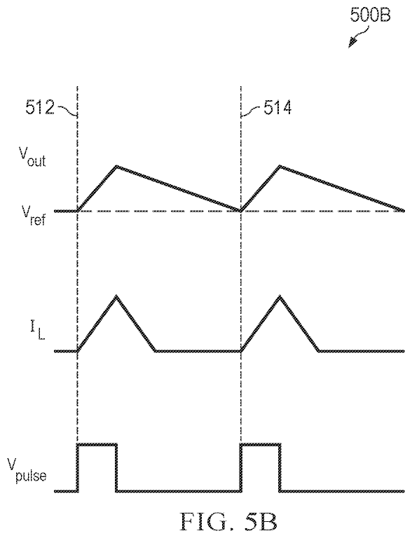

FIGS. 5A-5B are waveform diagrams illustrating examples 500A, 500B of light load operation. FIGS. 5A-5B illustrate values of Vₒᵤₜ, I_{L}, and Vₚᵤₗₛₑ during light load operation over time. The signals Vₒᵤₜ, Vₚᵤₗₛₑ may be the signals Vₒᵤₜ, Vₚᵤₗₛₑ described throughout the present disclosure. The signal I_{L} may be the current flowing through the inductor 114.

The example 500A corresponds to light load operation without the use of the drift compensation circuit 110. As shown, when Vₒᵤₜ falls below V_{ref}, a PFM pulse is sent at time 502. Since integrator drift is not compensated for, PFM “bursting” occurs, as illustrated by first, second, and third pulses of Vₚᵤₗₛₑ occurring at times 502, 504, 506 respectively. Each successive pulse within a PFM burst causes the output voltage Vₒᵤₜ to further rise, resulting in increased output voltage ripple. At time 508, Vₒᵤₜ again falls below V_{ref}. The process repeats, and PFM bursting occurs when sending a PFM pulse.

The example 500B corresponds to light load operation while using the drift compensation circuit 110. As shown, when Vₒᵤₜ falls below V_{ref}, a PFM pulse is sent at time 512. Since integrator drift is compensated for, PFM bursting does not occur. Since only a single PFM pulse is transmitted (rather than a burst of PFM pulses), the rise in Vₒᵤₜ is reduced, resulting in reduced output voltage ripple when compared to example 500A. At time 514, Vₒᵤₜ again falls below V_{ref}. The process repeats, and another PFM pulse is sent (without PFM bursting).

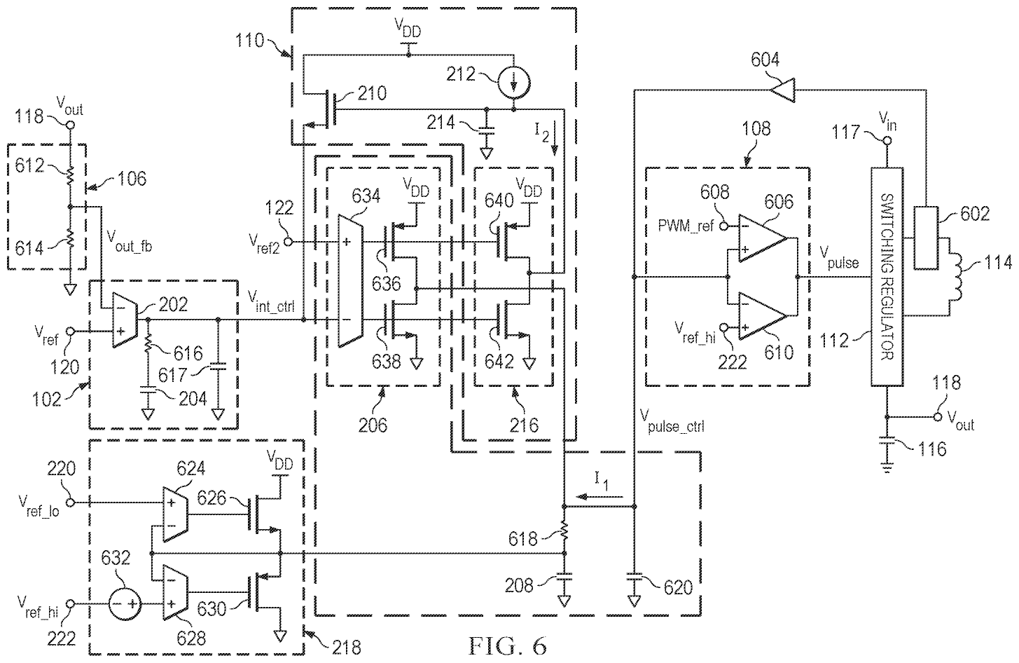

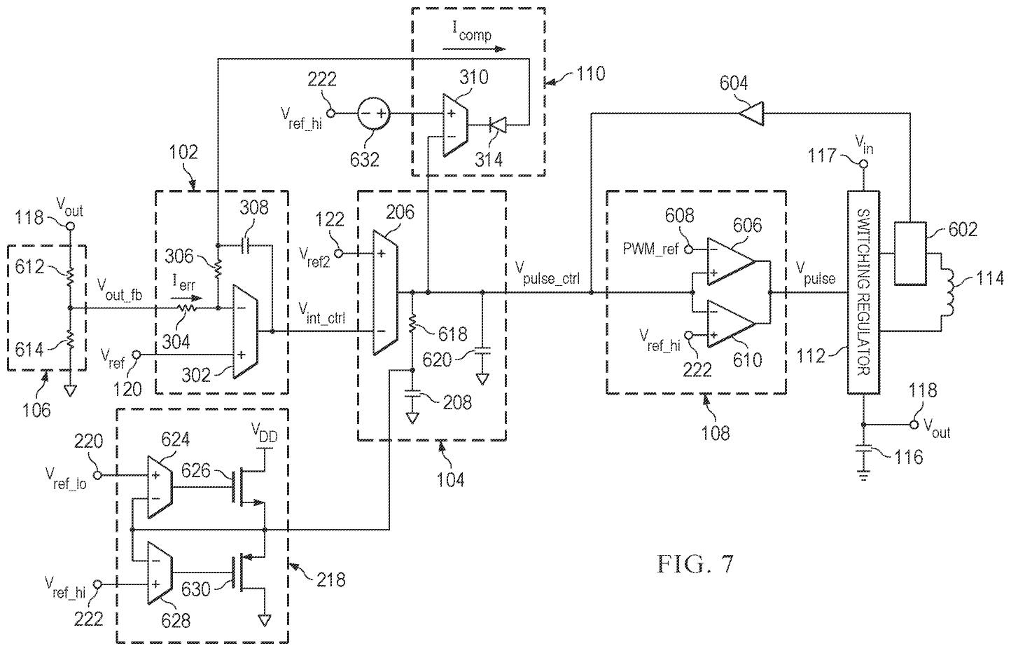

FIGS. 6 and 7 are circuit schematics illustrating examples of further details of FIGS. 2 and 3 respectively. Note, the details of FIG. 7 may also be applied to FIG. 4 where appropriate.

With reference to FIG. 6, similar to FIG. 2, FIG. 6 includes the first integrator 102, the second integrator 104, the feedback circuit 106, the pulse generator 108, the drift compensation circuit 110, the switching regulator 112, the inductor 114, the capacitor 116, the input terminal 117, the output terminal 118, the first reference voltage terminal 120, the second reference voltage terminal 122, the voltage clamp 218, the first amplifier 202, the first capacitor 204, the second amplifier 206, the second capacitor 208, the first transistor 210, the current source 212, the third capacitor 214, the current sensor 216, the input terminal 220, and the input terminal 222, which may be consistent with similarly numbered elements described with reference to FIG. 2.

With reference to FIG. 7, similar to FIG. 3, FIG. 7 includes the first integrator 102, the second integrator 104, the feedback circuit 106, the pulse generator 108, the drift compensation circuit 110, the switching regulator 112, the inductor 114, the capacitor 116, the input terminal 117, the output terminal 118, the first reference voltage terminal 120, the second reference voltage terminal 122, the first amplifier 302, the first resistor 304, the second resistor 306, the first capacitor 308, the second amplifier 206, the second capacitor 208, the third amplifier 310, and the diode 314, which may be consistent with similarly numbered elements described with reference to FIG. 3. Further illustrated is the voltage clamp 218, the input terminal 220, and the input terminal 222 (e.g., as described with reference to FIG. 2).

FIGS. 6 and 7 further illustrate a second current sensor 602, and a current feedback circuit 604. The pulse generator 108 includes a first comparator 606, a third reference voltage terminal 608, and a second comparator 610. The feedback circuit 106 includes a first resistor 612 and a second resistor 614. The first integrator 102 further includes a third resistor 616 and a fourth capacitor 617. The second integrator 104 further includes a fourth resistor 618 and a fifth capacitor 620. The voltage clamp 218 includes a third comparator 624, a second transistor 626, a fourth comparator 628, a third transistor 630, and (optionally) a voltage offset circuit 632. The second amplifier 206 includes an amplifier 634, a fourth transistor 636, and a fifth transistor 638. The current sensor 216 includes a sixth transistor 640, and a seventh transistor 642.

The second current sensor 602 has first and second sensing terminals coupled in series with the inductor 114, and an output terminal. As shown, the first sensing terminal is coupled to the first terminal of the switching regulator 112, and the second sensing terminal is coupled to the first terminal of the inductor 114. The current feedback circuit 604 has an input coupled to the output of the second current sensor 602, and an output coupled to the control input of the pulse generator.

The first comparator 606 has a first input coupled to the control input of the pulse generator 108, a second input coupled to the third reference voltage terminal 608, and an output coupled to the output of the pulse generator 108. The second comparator 610 has a first input coupled to the input terminal 222, a second input coupled to the control input of the pulse generator 108, and an output coupled to the output of the pulse generator 108.

The first resistor 612 has a first terminal coupled to the output terminal 118, and a second terminal coupled to the second input of the first integrator 102. The second resistor 614 has a first terminal coupled to the second terminal of the first resistor 612, and a second terminal coupled to ground.

The third resistor 616 has a first terminal coupled to the output of the first amplifier 202, and a second terminal coupled to the first terminal of the first capacitor 204. As shown, the second terminal of the first capacitor 204 is coupled to ground. The fourth capacitor 617 has a first terminal coupled to the output of the first amplifier 202, and a second terminal coupled to ground.

The fourth resistor 618 has a first terminal coupled to the output of the second integrator 104, and a second terminal coupled to the first terminal of the second capacitor 208. As shown, the second terminal of the second capacitor 208 is coupled to ground. The fifth capacitor 620 has a first terminal coupled to the output of the second integrator 104, and a second terminal coupled to ground.

The third comparator 624 has a first input coupled to the input terminal 220, a second input coupled to the output of the voltage clamp 218, and an output. The second transistor 626 has a first terminal coupled to a supply voltage (e.g., VDD), a second terminal coupled to the output of the voltage clamp 218, and a control input coupled to the output of the third comparator 624. The fourth comparator 628 has a first input, a second input coupled to the output of the voltage clamp 218, and an output. The third transistor 630 has a first terminal coupled to the output of the voltage clamp 218, a second terminal coupled to ground, and a control input coupled to the output of the fourth comparator 628. In some examples, the second transistor 626 is an NMOS transistor, and the third transistor 630 is a P-channel metal-oxide-semiconductor (PMOS) transistor.

In some examples, the first comparator 606 is a PWM comparator, and the second comparator 610 is a PFM comparator. Accordingly, the first comparator 606 is used for PWM operation, and the second comparator 610 is used for PFM operation. During PWM operation, the pulse generator 108 outputs the signal Vₚᵤₗₛₑ as a PWM signal. A signal PWM_ref is received on the third reference voltage terminal 608 which may be, for example, a triangle or sawtooth waveform. A duty cycle of the PWM signal may vary depending on a value of V_{pulse_ctrl} relative to PWM_ref. During PFM operation, the pulse generator 108 outputs the signal Vₚᵤₗₛₑ as a PFM signal. For example, the pulse generator 108 outputs a PFM pulse when V_{pulse_ctrl} falls below V_{ref_hi}. In some examples, the second comparator 610 outputs “high-Z” (e.g., the output is in a high impedance state) during PWM operation, and the first comparator 606 outputs high-Z during PFM operation.

With reference to FIG. 6, the voltage offset circuit 632 has a first terminal coupled to the first input of the fourth comparator 628, and a second terminal coupled to the input terminal 222. The amplifier 634 has a first input, a second input, a first output, and a second output. The first and second inputs of the amplifier 634 are coupled to the first and second inputs of the second integrator 104 respectively. The transistor 636 has a first terminal coupled to the supply voltage, a second terminal coupled to the output of the second integrator 104, and a control terminal coupled to the first output of the amplifier 634. The transistor 638 has a first terminal coupled to the second terminal of the transistor 636, a second terminal coupled to ground, and a control terminal coupled to the second output of the amplifier 634. The transistor 640 has a first terminal coupled to the supply voltage, a second terminal coupled to the output of the current sensor, and a control terminal coupled to the first output of the amplifier 634. The transistor 642 has a first terminal coupled to the second terminal of the transistor 640, a second terminal coupled to ground, and a control terminal coupled to the second output of the amplifier 634. In some examples, the transistors 636, 640 are PMOS transistors, and the transistors 638, 642 are NMOS transistors.

In some examples, the amplifier 634 is configured to provide signals (e.g., currents or voltages) at the first and second outputs of the amplifier 634 based on signals received on the first and second inputs of the amplifier 634. A signal at the first output and a signal at the second output may be used to set a current through the transistor 636 and the transistor 638 respectively. For example, when V_{ref2} is greater than V_{int_ctrl}, the amplifier 634 provides the first and second signals such that a current flowing from source to drain of the transistor 636 is greater than a current flowing from drain to source of the transistor 638, and the current I₁ flows left to right (e.g., opposite of the illustrated direction). In contrast, when V_{ref2} is less than V_{int_ctrl}, then the amplifier 634 provides the first and second signals such that the current flowing from source to drain of the transistor 636 is less than the current flowing from drain to source of the transistor 638, and the current I₁ flows right to left (e.g., in the illustrated direction).

In some examples, the transistors 640, 642 share the same or similar properties (e.g., transistor size, threshold voltage, etc.) as the transistors 636, 638. The control terminals (e.g., gates) of the transistors 640, 642 are coupled to the control terminals of the transistors 636, 638 respectively, and thus receive the same voltages. By using transistors with the same or similar properties, the current sensor 216 outputs a current I₂ that is the same as the current I₁ or proportional to the current I₁.

With reference to FIG. 7, the first input of the fourth comparator 628 is coupled to the input terminal 222. The voltage offset circuit 632 has a first terminal coupled to the first input of the third amplifier 310, and a second terminal coupled to the input terminal 222.

The methods are illustrated and described above as a series of operations or events, but the illustrated ordering of such operations or events is not limiting. For example, some operations or events may occur in different orders and/or concurrently with other operations or events apart from those illustrated and/or described herein. Also, some illustrated operations or events are optional to implement one or more aspects or examples of this description. Further, one or more of the operations or events depicted herein may be performed in one or more separate operations and/or phases. In some examples, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor, a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. Also, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of that parameter. Modifications are possible in the described examples, and other implementations are possible, within the scope of the claims.

What is claimed is:

1. A circuit, comprising:
a first integrator having a first input, a second input, and an output;
a second integrator having a first input, a second input coupled to the output of the first integrator, and an output;
a pulse generator having a control input coupled to the output of the second integrator, and an output; and
a drift compensation circuit having a first terminal coupled to the output of the second integrator, and a second terminal coupled to the output of the first integrator.

2. The circuit of claim 1, wherein the second integrator comprises:
a first amplifier having a first input, a second input, and an output coupled to the first input, second input, and output of the second integrator respectively;
a first resistor having a first terminal coupled to the output of the first amplifier, and a second terminal; and
a first capacitor having a first terminal coupled to the second terminal of the first resistor, and a second terminal.

3. The circuit of claim 2, wherein the drift compensation circuit comprises:
a first transistor having a first terminal coupled to a supply voltage, a second terminal coupled to the second terminal of the drift compensation circuit, and a control terminal;
a current source having a first terminal coupled to the first terminal of the first transistor, and a second terminal coupled to the first terminal of the drift compensation circuit; and
a second capacitor having a first terminal coupled to the control terminal of the first transistor, and a second terminal coupled to ground;
wherein the circuit further comprises a current sensor having sensing terminals coupled in series with the output of the second integrator, and an output coupled to the first terminal of the second capacitor.

4. The circuit of claim 3, wherein the first integrator comprises:
a second amplifier having a first input, a second input, and an output coupled to the first input, the second input, and the output of the first integrator respectively;
a second resistor having a first terminal couple to the output of the second amplifier, and a second terminal; and
a second capacitor having a first terminal coupled to the second terminal of the second resistor, and a second terminal.

5. The circuit of claim 3, further comprising a voltage clamp having a first input, a second input, and an output coupled to the first terminal of the first capacitor, the voltage clamp comprising:
a first comparator having a first input coupled to the first input of the voltage clamp, a second input coupled to the output of the voltage clamp, and an output;
a first transistor having a first terminal, a second terminal coupled to the output of the voltage clamp, and a control terminal coupled to the output of the first comparator;
a second comparator having a first input, a second input coupled to the output of the voltage clamp, and an output;
a second transistor having a first terminal coupled to the output of the voltage clamp, a second terminal, and a control terminal coupled to the output of the second comparator; and
a voltage offset circuit having a first terminal coupled to the first input of the second comparator, and a second input coupled to the second input of the voltage clamp.

6. The circuit of claim 1, further comprising:
a switching regulator having a control input coupled to the output of the pulse generator, and an output coupled; and
a feedback circuit having a first terminal coupled to the output of the switching regulator, and a second terminal coupled to the second input of the first integrator.

7. The circuit of claim 6, wherein the feedback circuit comprises:
a first resistor having a first terminal coupled to the first terminal of the feedback circuit, and a second terminal coupled to the second terminal of the feedback circuit; and
a second resistor having a first terminal coupled to the second terminal of the first resistor, and a second terminal coupled to ground.

8. The circuit of claim 6, further comprising:
a current sensor having sensing terminals coupled in series with an inductor of the switching regulator, and an output coupled to the output of the second integrator.

9. The circuit of claim 1, wherein the pulse generator includes a pulse frequency modulation (PFM) comparator having a first input, and a second input coupled to the control input of the pulse generator.

10. The circuit of claim 9, wherein the pulse generator further includes a pulse width modulation comparator having a first input coupled to the control input of the pulse generator, and a second input.

11. A circuit, comprising:
a first integrator having a first input, a second input, and an output, the first integrator including:
a first amplifier having a first input coupled to the first input of the first integrator, a second input, and an output coupled to the output of the first integrator;
a first resistor having a first terminal coupled to the second input of the first integrator, and a second terminal coupled to the second input of the first amplifier;
a second resistor having a first terminal coupled to the second input of the first integrator, and a second terminal;
a first capacitor having a first terminal coupled to the second terminal of the second resistor, and a second terminal coupled to the output of the first amplifier; and
a drift compensation circuit having a first terminal coupled to the output of the first integrator, a second terminal coupled to the first terminal of the first capacitor, and a third terminal.

12. The circuit of claim 11, wherein the drift compensation circuit comprises:
a second amplifier having a first input coupled to the third terminal of the drift compensation circuit, a second input coupled to the first terminal of the drift compensation circuit, and an output; and
a diode having a first terminal coupled to the second terminal of the drift compensation circuit, and a second terminal coupled to the output of the second amplifier.

13. The circuit of claim 11, further comprising a second integrator coupled between the output of the first integrator and the first terminal of the drift compensation circuit, the second integrator comprising:
a second amplifier having a first input, a second input coupled to the output of the first amplifier, and an output; and
a second capacitor having a first terminal coupled to the output of the second amplifier, and a second terminal coupled to ground.

14. The circuit of claim 11, further comprising a voltage clamp having a first input, a second input, and an output coupled to the first terminal of the first capacitor, the voltage clamp comprising:
a first comparator having a first input coupled to the first input of the voltage clamp, a second input coupled to the output of the voltage clamp, and an output;
a first transistor having a first terminal, a second terminal coupled to the output of the voltage clamp, and a control terminal coupled to the output of the first comparator;
a second comparator having a first input coupled to the second input of the voltage clamp, a second input coupled to the output of the voltage clamp, and an output; and
a second transistor having a first terminal coupled to the output of the voltage clamp, a second terminal, and a control terminal coupled to the output of the second comparator.

15. A circuit, comprising:
a first integrator including:
a first amplifier having a first input, a second input, and an output; and
a first capacitor coupled to the output of the first amplifier;
a second integrator including:
a second amplifier having a first input, a second input coupled to the output of the first amplifier, and an output; and
a second capacitor coupled to the output of the second amplifier; and
a drift compensation circuit having a sensing terminal coupled to the output of the second amplifier, and an output terminal coupled to the first capacitor;
wherein the drift compensation circuit is configured to provide a current to the first capacitor based on a current or voltage sensed at the output of the second amplifier.

16. The circuit of claim 15, further comprising:
a first plurality of integrators including a plurality of respective capacitors, wherein the first plurality of integrators includes the first integrator;
a selection circuit having a plurality of inputs coupled to respective outputs of the first plurality of integrators, and an output coupled to the second input of the second amplifier; and
a plurality of switches having a plurality of respective first terminals and second terminals, the plurality of first terminals coupled to the plurality of respective capacitors, and the second terminals coupled to the output terminal of the drift compensation circuit.

17. The circuit of claim 15, wherein the drift compensation circuit further includes a reference voltage terminal, the drift compensation circuit configured to provide the current to the first capacitor based on voltage sensed at the output of the second amplifier relative to a voltage at the reference voltage terminal.

18. The circuit of claim 17, further comprising:
a pulse generator having a control input coupled to the output of the second amplifier, a reference input, and an output; and
a voltage offset circuit having a first terminal coupled to the reference voltage terminal of the drift compensation circuit, and a second terminal coupled to the reference input of the pulse generator.

19. The circuit of claim 18, further comprising:
a switching converter having a control input coupled to the output of the pulse generator, and an output; and
a current feedback circuit having first and second sensing terminals coupled in series with an inductor of the switching converter, and an output coupled to the output of the second amplifier.

20. The circuit of claim 19, further comprising a feedback circuit having a first terminal coupled to the output of the switching converter, and a second terminal coupled to the second input of the first amplifier.
